(19) United States
(12) Patent Application Publication
(10) Pub. No.: US 2025/0030129 A1
(43) Pub. Date: Jan. 23, 2025

(54) RECHARGEABLE BATTERY MODULE

(71) Applicant: SAMSUNG SDI CO., LTD., Yongin-si (KR)

(72) Inventors: Hyeok LEE, Yongin-si (KR); Young-Hwan KWON, Yongin-si (KR)

(21) Appl. No.: 18/651,778

(22) Filed: May 1, 2024

(30) Foreign Application Priority Data
Jul. 21, 2023 (KR) 10-2023-0095514

(51) Int. Cl. H01M 50/503; H01M 50/505; H01M 50/519; H05K 1/02

(52) U.S. Cl. CPC H01M 50/503; H01M 50/505; H01M 50/519; H01M 2220/30; H05K 1/0277; H05K 2201/055

(57) ABSTRACT

A rechargeable battery module is disclosed. The rechargeable battery module includes a busbar holder covering a plurality of battery cells, a busbar disposed on the busbar holder to electrically connect the battery cells, and a flexible printed circuit (FPC) attached to the busbar to send a signal and to detect a current from the busbar, wherein the flexible printed circuit includes a thin copper film attached between the inner surfaces of a pair of cover layers, wherein the thin copper film is exposed in unit thin film portions through a plurality of openings formed in the pair of cover layers, the thin copper film and the pair of cover layers are bent, and the unit thin film portions are formed in multiple layers and welded to the busbar.

### CROSS-REFERENCE TO RELATED APPLICATION

This application claims priority to and the benefit of Korean Patent Application No. 10-2023-0095514 filed in the Korean Intellectual Property Office on Jul. 21, 2023, the entire contents of which are incorporated herein by reference.

### BACKGROUND OF THE INVENTION

### (a) Field of the Invention

The present disclosure relates to a rechargeable battery module, and more particularly, to a rechargeable battery module that connects a sensing portion of a flexible printed circuit (FPC) to a busbar.

### (b) Description of the Related Art

Unlike primary batteries, rechargeable batteries are batteries that can be repeatedly charged and discharged. Small-capacity rechargeable batteries are used in small, portable electronic devices such as mobile phones, laptop computers, and camcorders.

High-capacity and high-density secondary batteries are used as power sources for driving motors in hybrid and electric vehicles or for energy storage. The rechargeable batteries may be used by forming a rechargeable battery module including a plurality of battery cells connected in series and/or parallel to drive a motor of, for example, a hybrid vehicle that requires relatively high energy density.

The rechargeable battery module is equipped with a flexible printed circuit (FPC) that detects a voltage or current from the busbar and transmits a detection signal. The FPC sensing structure solders the FPC to a separate nickel tab (Ni-Tab) and welds the tab to an aluminum (Al) busbar.

Nickel tabs (Ni-tab), however, are associated with increased costs because they require raw nickel, a soldering process to form junctions, a coating process to form an anti-corrosion coating, and jigs for guides.

Deformation (e.g., S deform) of the FPC causes sagging during movement due to the nickel tab. Such sagging in FPC can occur during the welding of the aluminum busbar and the nickel tab It is therefore difficult to form the in-position junction of the FPC and the nickel tab for the busbar.

### SUMMARY OF THE INVENTION

The present disclosure provides a rechargeable battery module capable of directly bonding of a flexible printed circuit (FPC) to a busbar. The present disclosure also provides a rechargeable battery module that enables in-position junction of the flexible printed circuit (FPC) to the busbar.

A rechargeable battery module according to an embodiment of the present disclosure includes: a busbar holder covering a plurality of battery cells, a busbar disposed on the busbar holder to electrically connect the battery cells; and a flexible printed circuit (FPC) attached to the busbar for sending a signal and detecting a current in the busbar, wherein the flexible printed circuit includes a thin copper film attached between the inner surfaces of a pair of cover layers, wherein the thin copper film is exposed in unit thin film portions through a plurality of openings formed in the pair of cover layers, the thin copper film and the pair of cover layers are bent, and the unit thin film portions are formed in multiple layers and welded to the busbar.

The unit thin film portion has a thickness of 0.035 mm, and the total thickness of the multiple layers is equal to 0.035 mm multiplied by the number of layers.

The flexible printed circuit includes: a main line portion disposed in a first direction on the busbar holder; and a branch line portion protruding from the main line portion in a second direction intersecting the first direction, and disposed further in the first direction. The unit thin film portions may be connected to the branch line portion.

The branch line portion is attached to the busbar.

In some embodiments, the rechargeable battery module has two unit thin film portions connected in the first direction.

The unit thin film portions may include a first unit portion and a second unit portion continuously extending along the first direction, and the first unit portion and the second unit portion may be bent and overlapped with each other around a second direction bending axis set in the second direction.

The first unit portion may include a first plane portion connected to a first inclined portion at a first inclined angle θ1, the second unit portion may include a second plane portion connected to a second inclined portion at a second inclined angle θ2 that is greater than the first inclined angle, and the first plane portion and the second plane portion may be connected in the second direction, sequentially stacked on the busbar, and welded to the busbar.

In some embodiments, the rechargeable battery module has two unit thin film portions connected in the second direction.

The unit thin film portions may include a first unit portion and a second unit portion continuously extending along the second direction, and the first unit portion and the second unit portion may be bent and overlapped with each other around a first direction bending axis set in the first direction.

The first unit may include a first plane portion connected to the first inclined portion at a first inclination angle θ21, the second unit portion may include the second plane portion connected to the second inclined portion at a second inclined angle θ22 that is greater than the first inclined angle, and the first plane portion and the second plane portion may be connected in the first direction, sequentially stacked on the busbar, and welded to the busbar.

In some embodiments, the rechargeable battery module has three unit thin film portions connected in the second direction.

The unit thin film portions may include a first unit portion, a second unit portion and a third unit portion continuously extending along the second direction, wherein the first unit portion and the second unit portion may be bent and overlapped with each other around a first direction bending axis set in the first direction, and the second unit portion and the third unit portion may be bent and overlapped with each other around another first direction bending axis set in the first direction.

The first unit portion may include the first plane portion connected to the first inclined portion at a first inclined angle θ31, the second unit portion may include the second plane portion connected to the second inclined portion at a second inclined angle θ32 that is greater than the first inclined angle, the third unit portion may include a third plane portion connected to a third inclined portion at a third inclined angle θ33 greater than the second inclined angle, and the first plane portion, the second plane portion, and the third plane portion may be connected in the second direction, sequentially stacked on the busbar, and welded to the busbar.

In some embodiments, the rechargeable battery module has three unit thin film portions connected in the first direction.

The unit thin film portions may include a first unit portion, a second unit portion and a third unit portion continuously extending along the first direction, wherein the first unit portion and the second unit portion may be bent and overlapped with each other around a second direction bending axis set in the second direction, and the second unit portion and the third unit portion may be bent and overlapped with each other around another second direction bending axis set in the second direction.

The unit thin film portions may include a first unit portion, a second unit portion, a third unit portion and a fourth unit portion continuously extending along the first direction, wherein the first unit portion and the second unit portion may be bent and overlapped with each other around a second direction bending axis set in the second direction, the second unit portion and the third unit portion may be bent and overlapped with each other around another second direction bending axis set in the second direction, and the third unit portion and the fourth unit portion may be bent and overlapped with each other around the other second direction bending axis set in the second direction.

In some embodiments, the rechargeable battery module has four unit thin film portions connected in the first direction and the second direction. The unit thin film portions may include a first unit portion and a second unit portion continuously extending along the first direction, and a third unit portion and a fourth unit portion continuously extending along the second direction to the first unit portion and the second unit portion, and continuously extending along the first direction.

According to the rechargeable battery module of an embodiment, the thin copper film is exposed in the unit thin film portions through a plurality of openings formed in the cover layer, the thin copper film and the cover layer are bent, and the unit thin film portions are formed in multiple layers and welded to the busbar made of aluminum.

Therefore, according to an embodiment, unit thin film portions made of copper are formed in multiple layers, thereby directly bonding a flexible printed circuit (FPC) and a busbar made of aluminum. Additionally, according to an embodiment, it is possible to bond the flexible printed circuit (FPC) to the busbar in the correct position.

### BRIEF DESCRIPTION OF THE DRAWINGS

FIG. 1 is a partial cross-sectional view of a rechargeable battery module according to a first embodiment of the present disclosure.

FIG. 2 is a perspective view of a busbar, a flexible printed circuit, and a unit thin film portion of FIG. 1 before bending.

FIG. 3 is a perspective view of the unit thin film portion of FIG. 2 during bending.

FIG. 4 is a top plan view of the unit thin film portion of FIG. 2 in a completed state of bending.

FIG. 5 is a cross-sectional view taken along line V-V of the bent unit thin film portions of FIG. 4 arranged on a busbar.

FIG. 6 is a cross-sectional view taken along line V-V of the unit thin film portions of FIG. 5 welded on a busbar.

FIG. 7 is a top plan view of the busbar, flexible printed circuit, and unit thin film portion in the rechargeable battery module according to the second embodiment of the present disclosure before bending.

FIG. 8 is a top plan view of the unit thin film portion of FIG. 7 in a completed state of bending.

FIG. 9 is a cross-sectional view taken along line IX-IX of the bent unit thin film portions of FIG. 8 arranged on a busbar.

FIG. 10 is a cross-sectional view taken along line IX-IX of the unit thin film portions of FIG. 8 welded on a busbar.

FIG. 11 is a perspective view of the busbar, flexible printed circuit, and unit thin film portion in the rechargeable battery module according to the third embodiment of the present disclosure before bending.

FIG. 12 is a perspective view of the unit thin film portion of FIG. 11 in a completed state of bending.

FIG. 13 is a cross-sectional view taken along line XIII-XIII of the bent unit thin film portions of FIG. 12 arranged on a busbar.

FIG. 14 is a cross-sectional view taken along line XIII-XIII of the unit thin film portions of FIG. 12 welded on a busbar.

FIG. 15 is a top plan view of the busbar, flexible printed circuit, and unit thin film portion in the rechargeable battery module according to the fourth embodiment of the present disclosure before bending.

FIG. 16 is a perspective view of the primary and secondary bending states of the flexible printed circuit and the unit thin film portion in the rechargeable battery module according to the fifth embodiment of the present disclosure.

FIG. 17 is a perspective view of the unit thin film portion of FIG. 16 in the third bending completed state.

FIG. 18 is a top plan view of the busbar, flexible printed circuit, and unit thin film portion in the rechargeable battery module according to the sixth embodiment of the present disclosure before bending.

### DETAILED DESCRIPTION OF THE EMBODIMENTS

Hereinafter, the present disclosure will be described more fully with reference to the accompanying drawings, in which exemplary embodiments of the invention are shown. As those skilled in the art will realize, the described embodiments may be modified in various different ways, all without departing from the scope of the present disclosure. The drawings and description are to be regarded as illustrative in nature and not restrictive. Like reference numerals designate like elements throughout the specification.

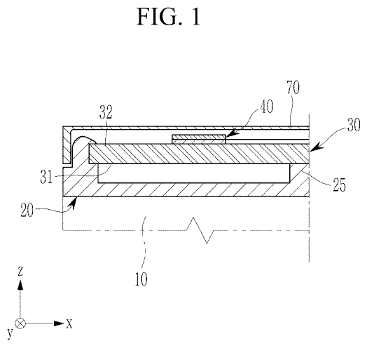

FIG. 1 is a partial cross-sectional view of a rechargeable battery module according to a first embodiment of the present disclosure. Referring to FIG. 1, the rechargeable battery module of the first embodiment includes a plurality of battery cells 10 formed of rechargeable batteries, a busbar holder 20, a busbar 30, and a flexible printed circuit (FPC) 40.

The rechargeable battery module of the first embodiment may have module frames of various structures, but detailed description of this configuration will be omitted and will be described as an example. A plurality of battery cells 10 are formed as rechargeable batteries and are stacked in a first direction (x-axis direction).

A pair of end plates is disposed on both ends of the stacked battery cells 10 in the first direction to constrain the battery cells 10 in the first direction (x-axis direction). A pair of side plates are disposed on both sides of the second direction (y-axis direction) of the battery cells 10 intersecting the first direction, and are connected to a pair of end plates to constrain the battery cells 10 in the second direction.

The battery cells 10 may be disposed in one or two rows. When disposed in two rows, an additional center plate may be disposed between a pair of side plates. The center plate is disposed in the first direction between the two rows of battery cells 10 to constrain the battery cells 10 in the second direction on both sides.

The busbar holder 20 may include a busbar support 25 for connecting and insulating the electrode terminals (not shown) of the battery cells 10, and a vent portion for discharging vent gas of the battery cells 10 (not shown).

The busbar support 25 exposes the electrode terminals in the third direction (height of the battery cell, z-axis direction) to cover the other portions of the battery cells 10 while supporting the busbar 30 that connects the electrode terminals in series or parallel. The third direction (height of the battery cell, z-axis direction) intersects the first direction (thickness of the battery cell, x-axis direction) and the second direction (length of the battery cell, y-axis direction).

The flexible printed circuit (FPC) 40 is configured to be attached to the busbar 30, to detect a current flowing in the busbar 30 that electrically connects the battery cells 10, and to send a detection signal to the battery management system (BMS).

The rechargeable battery module of the first embodiment may further include a top cover 70. The top cover 70 is disposed on the busbar 30, and is coupled to the busbar holder 20 from the outside to cover a plurality of busbars (not shown) and the busbar holder 20.

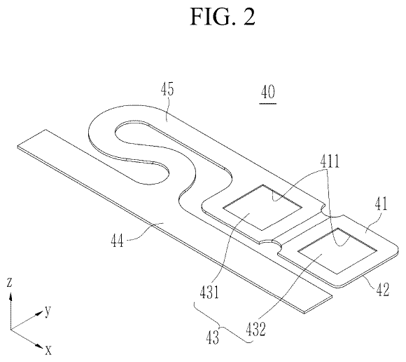

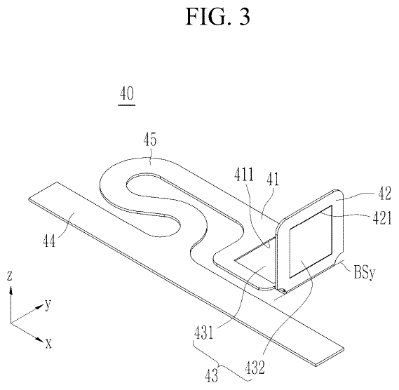

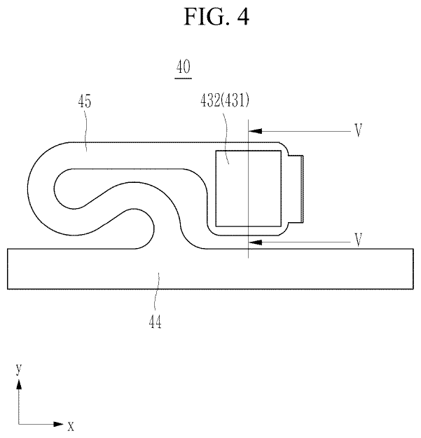

FIG. 2 is a perspective view of a busbar, a flexible printed circuit, and a unit thin film portion of FIG. 1 before bending, FIG. 3 is a perspective view of the unit thin film portion of FIG. 2 during bending, and FIG. 4 is a top plan view of the unit thin film portion of FIG. 2 in a completed state of bending.

Referring to FIGS. 2 to 4, the flexible printed circuit 40 is formed by providing a thin copper film between the inner surfaces of a pair of cover layers 41 and 42 attached to each other. The thin copper film is exposed in unit thin film portions 43 through a plurality of openings 411 and 421 formed in the cover layers 41 and 42.

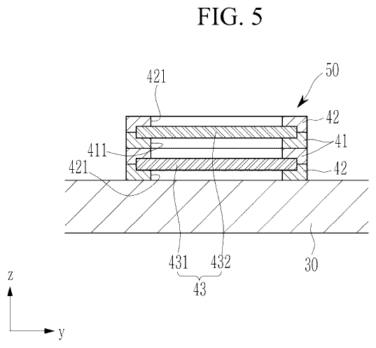

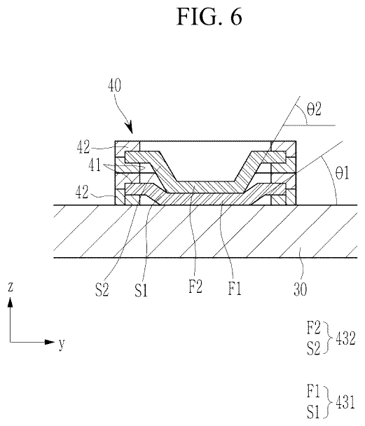

FIG. 5 is a cross-sectional view taken along line V-V of the bent unit thin film portions of FIG. 4 arranged on a busbar, and FIG. 6 is a cross-sectional view taken along line V-V of the unit thin film portions of FIG. 5 welded on a busbar.

Referring to FIGS. 5 and 6, the thin copper film and the cover layers 41 and 42 are bent, and the unit thin film portions 43 are formed in multiple layers and welded to the busbar 30 made of aluminum. In this way, the multiple layers of unit thin film portions 43 enable and strengthen the welding between dissimilar materials such as copper and aluminum.

Since the flexible printed circuit 40 does not use nickel tabs, the flexible printed circuit 40 does not significantly deform and sag during movement. Therefore, the multiple layers of unit thin film portions 43 facilitates in-position junction of the flexible printed circuit 40 and the busbar 40.

Since the unit thin film portion 43 has a thickness of 0.035 mm, the total thickness of the multiple layers is equal to 0.035 mm multiplied by the number of layers.

In the first embodiment, the two-layer unit thin film portions 43 have a thickness of 0.07 mm, which is twice that of 0.035 mm.

Since the two-layer unit thin portions 43 formed by bending have improved mechanical strength compared to the one-layer structure, it is possible to effectively prevent tearing, piercing during welding, and pinhole failure during movement and handling, for direct junction to the aluminum busbar 30.

Referring again to FIGS. 2 to 4, the flexible printed circuit 40 includes a main line portion 44 and a branch line portion 45. The main line portion 44 is disposed on the busbar holder 20 in the first direction (x-axis direction). The branch line portion 45 is connected to and protrudes from the main line portion 44 in the second direction (y-axis direction) intersecting the first direction and is disposed further in the first direction.

The unit thin film portions 43 are parts joined to the busbar 30 and are connected to the branch line portion 45. The branch line unit 45 is disposed corresponding to the busbar 30. In the first embodiment, there are two unit thin film portions 43 that are connected in the first direction (x-axis direction).

The unit thin film portions 43 include a first unit portion 431 and a second unit portion 432 that continuously extend along the first direction (x-axis direction). The first unit portion 431 and the second unit portion 432 are bent and overlapped with each other around a second direction bending axis BSy set in the second direction (y-axis direction).

Referring again to FIGS. 5 and 6, in the welded state, the first unit portion 431 includes a first plane portion F1 connected to a first inclined portion S1 at the first inclined angle θ1, and the second unit portion 432 includes a second plane portion F2 connected to a second inclined portion S2 at a second inclined angle θ2 that is greater than the first inclined angle θ1.

The first plane portion F1 and the second plane portion F2 are connected in the second direction (y-axis direction), are sequentially stacked on the busbar 30, and are welded to the busbar 30. Compared to a one-layer structure, the first plane portion F1 and the second plane portion F2 forming a two-layer structure may effectively prevent piercing and pinhole defects during welding. And the current signal of the bus bar 30 is transmitted to the branch line portion 45 and the main line portion 44 via the first inclined portion S1 and the second inclined portion S2 through the welded first plane portion F1 and the second plane portion F2.

In the flexible printed circuit 40 of the first embodiment, compared to the main line portion 44, the branch line portion 45 and the unit thin film portions 43 generate scrap on both sides of the x-axis direction. The flexible printed circuit 40 of the first embodiment allows the formation of unit thin film portions 43 while minimizing the generation of such scrap.

Hereinafter, various embodiments of the present disclosure will be described. Compared to the first embodiment and the previously described embodiments, descriptions of the same components will be omitted and descriptions of different components will be described.

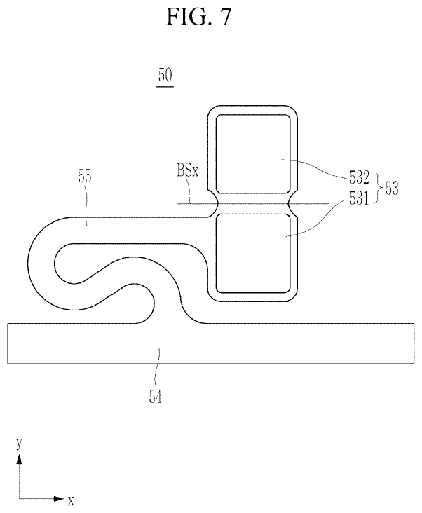

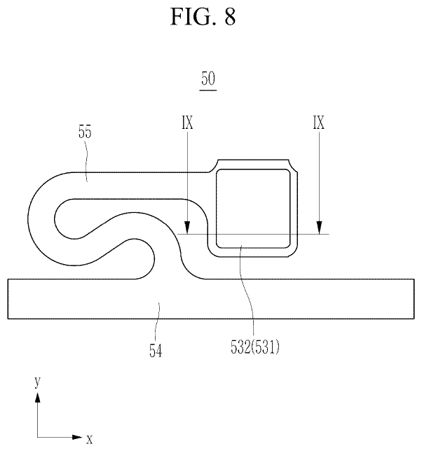

FIG. 7 is a top plan view of the busbar, flexible printed circuit, and unit thin film portion in the rechargeable battery module according to a second embodiment of the present disclosure before bending, and FIG. 8 is a top plan view of the unit thin film portion of FIG. 7 in a completed state of bending. Referring to FIGS. 7 and 8, in the second embodiment, there are two unit thin film portions of a flexible printed circuit 50 that are connected in the second direction (y-axis direction).

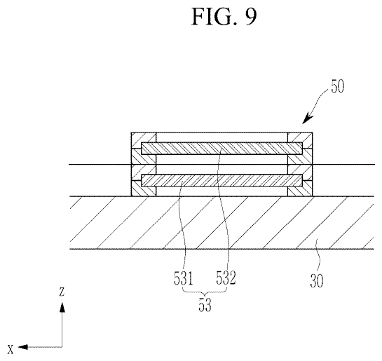

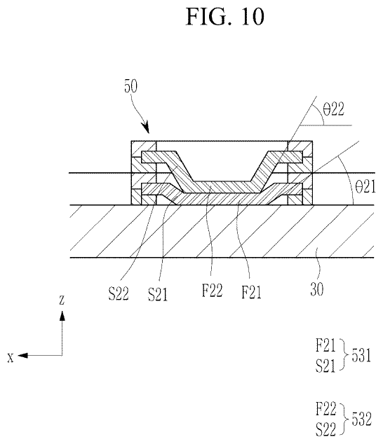

FIG. 9 is a cross-sectional view taken along line IX-IX of the bent unit thin film portions of FIG. 8 arranged on a busbar, and FIG. 10 is a cross-sectional view taken along line IX-IX of the unit thin film portions of FIG. 8 welded on a busbar.

Referring to FIGS. 7 to 10, unit thin film portions 53 include a first unit portion 531 and a second unit portion 532 continuously extending along the second direction (y-axis direction). The first unit portion 531 and the second unit portion 532 are bent and overlapped with each other around a first direction bending axis BSx set in the first direction (x-axis direction).

In a welded state, the first unit portion 531 includes a first plane portion F21 connected to a first inclined portion S21 at the first inclined angle θ21, and the second unit portion 532 includes a second plane portion F22 connected to a second inclined portion S22 at a second inclined angle θ22 that is greater than the first inclined angle θ21.

The first plane portion F21 and the second plane portion F22 are connected in the first direction (x-axis direction), are sequentially stacked on the busbar 30, and are welded to the busbar 30. Compared to a one-layer structure, the first plane portion F21 and the second plane portion F22 forming a two-layer structure may effectively prevent piercing and pinhole defects during welding. And the current signal of the bus bar 30 is transmitted to a branch line portion 55 and a main line portion 54 via the first inclined portion S21 and the second inclined portion S22 through the welded first plane portion F21 and the second plane portion F22.

In the flexible printed circuit 50 of the second embodiment, compared to the main line portion 54, the branch line portion 55 and the unit thin film portions 53 generate scrap on both sides of the x-axis direction. The flexible printed circuit 50 of the second embodiment generates more scrap on both sides of the x-axis direction of the second unit portion 532 than the flexible printed circuit 40 of the first embodiment in forming the unit thin film portions 53.

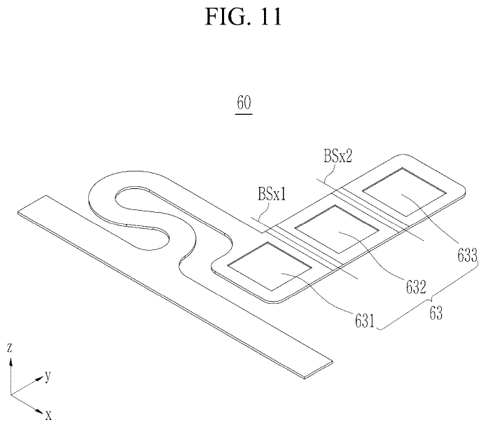

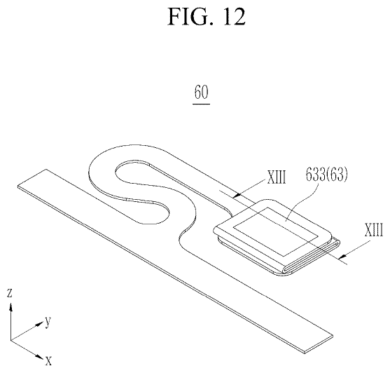

FIG. 11 is a perspective view of the busbar, flexible printed circuit, and unit thin film portion in the rechargeable battery module according to a third embodiment of the present disclosure before bending, and FIG. 12 is a perspective view of the unit thin film portion of FIG. 11 in a completed state of bending. Referring to FIGS. 11 and 12, in the third embodiment, the unit thin film portions of a flexible printed circuit 60 are formed of three and connected in the second direction (y-axis direction).

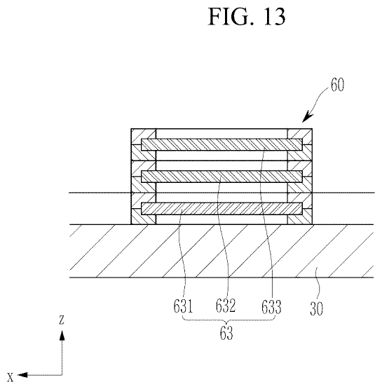

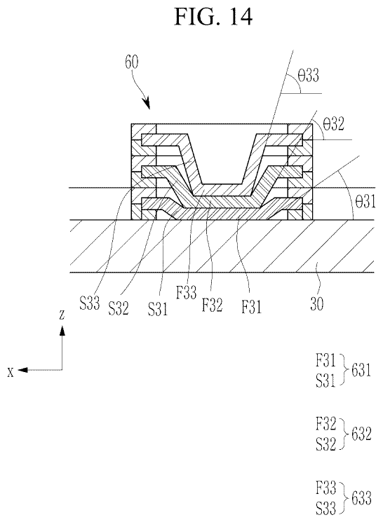

FIG. 13 is a cross-sectional view taken along line XIII-XIII of the bent unit thin film portions of FIG. 12 arranged on a busbar, and FIG. 14 is a cross-sectional view taken along line XIII-XIII of the unit thin film portions of FIG. 12 welded on a busbar.

Referring to FIGS. 11 to 14, unit thin film portions 63 include a first unit portion 631, a second unit portion 632, and a third unit portion 633. The first unit portion 631 and the second unit portion 632 are bent and overlapped with each other around a first direction bending axis BSx1 set in the first direction (x-axis direction). The second unit portion 632 and the third unit portion 633 are bent and overlapped with each other around another first direction bending axis BSx2 set in the first direction (x-axis direction).

In a welded state, the first unit portion 631 includes a first plane portion F31 connected to a first inclined portion S31 at a first inclined angle 631, the second unit portion 632 includes a second plane portion F32 connected to a second inclined portion S32 at a second inclined angle θ32 that is greater than the first inclined angle 631, and the third unit portion 633 includes a third plane portion F33 connected to a third inclined portion S33 at a third inclined angle 633 that is greater than the second inclined angle θ32.

The first plane portion F31, the second plane portion F32, and the third plane portion F33 are connected in the second direction (y-axis direction), are sequentially stacked on the busbar 30, and are welded to the busbar 30. Compared to a one-layer structure or a two-layer structure, the first plane portion F31, the second plane portion F32 and the third plane portion F33 forming a three-layer structure may effectively prevent piercing and pinhole defects during welding. And the current signal of the bus bar 30 is transmitted to the branch line portion 55 and a main line portion 54 via the first inclined portion S31, the second inclined portion S32, and the third inclined portion S33 through the welded first plane portion F31, the second plane portion F32, and the third plane portion F33.

In the flexible printed circuit 60 of the third embodiment, the unit thin film portions 63 generate scrap on both sides of the x-axis direction. The flexible printed circuit 60 of the third embodiment generates more scrap on both sides of the x-axis direction of the second unit portion 632 and the third unit portion 633 than the flexible printed circuit 40 of the first embodiment in forming the unit thin film portions 63.

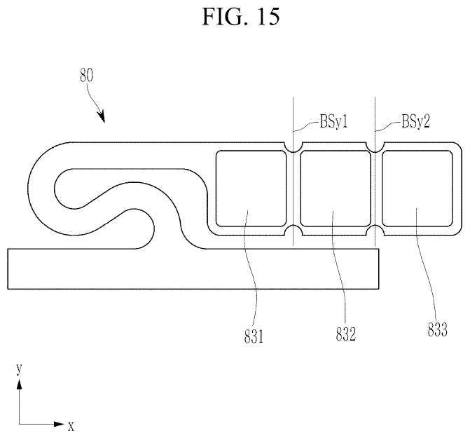

FIG. 15 is a top plan view of the busbar, flexible printed circuit, and unit thin film portion in the rechargeable battery module according to a fourth embodiment of the present disclosure before bending. Referring to FIG. 15, in the fourth embodiment, the unit thin film portions of a flexible printed circuit 80 are formed of three and connected in the first direction (x-axis direction).

Unit thin film portions 83 include a first unit portion 831, a second unit portion 832 and a third unit portion 833 that continuously extend along the first direction (x-axis direction). The first unit portion 831 and the second unit portion 832 are bent and overlapped with each other around a second direction bending axis BSy1 set in the second direction (y-axis direction). The second unit portion 832 and the third unit portion 833 are bent and overlapped with each other around another second direction bending axis BSy2 set in the second direction (y-axis direction).

Compared to a one-layer structure or a two-layer structure, the first plane portion 831, the second plane portion 832 and the third plane portion 833 forming a three-layer structure may effectively prevent piercing and pinhole defects during welding.

In the flexible printed circuit 80 of the fourth embodiment, the unit thin film portions 83 generate scrap on both sides of the x-axis direction. The flexible printed circuit 80 of the fourth embodiment, in forming the unit film portions 83, compared to the flexible printed circuit 40 of the first embodiment, generates less scrap on both sides in the x-axis direction because the flexible printed circuit 80 further includes the second unit portion 832 and the third unit portion 833.

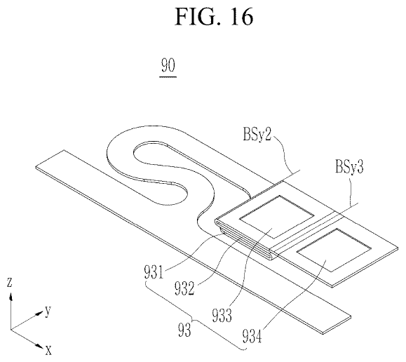

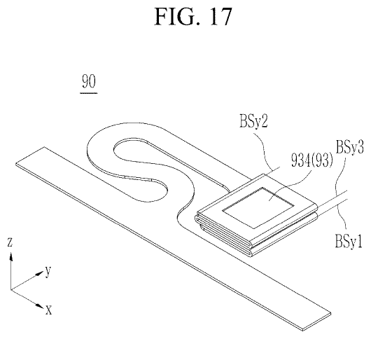

FIG. 16 is a perspective view of the primary and secondary bending states of the flexible printed circuit and the unit thin film portion in the rechargeable battery module according to a fifth embodiment of the present disclosure, and FIG. 17 is a perspective view of the unit thin film portion of FIG. 16 in the third bending completed state. Referring to FIGS. 16 and 17, in the fifth embodiment, the unit thin film portions of a flexible printed circuit 90 are formed of four and connected in the first direction (x-axis direction).

Unit thin film portions 93 include a first unit portion 931, a second unit portion 932, a third unit portion 933 and a fourth unit portion 934 that continuously extend along the first direction (x-axis direction). The first unit portion 931 and the second unit portion 932 are bent and overlapped with each other around the second direction bending axis BSy1 set in the second direction (y-axis direction). The second unit portion 932 and the third unit portion 933 are bent and overlapped with each other around another second direction bending axis BSy2 set in the second direction (y-axis direction). The third unit portion 933 and the fourth unit portion 934 are bent and overlapped with each other around the other second direction bending axis BSy3 set in the second direction (y-axis direction).

Compared to a one-layer structure, a two-layer structure or a three-layer structure, the first plane portion 931, the second plane portion 932, the third plane portion 933 and the fourth unit portion 934 forming a four-layer structure may effectively prevent piercing and pinhole defects during welding.

In the flexible printed circuit 90 of the fifth embodiment, the unit thin film portions 93 generate scrap on both sides of the x-axis direction. The flexible printed circuit 90 of the fifth embodiment, in forming the unit film portions 93, compared to the flexible printed circuit 40 of the first embodiment, generates less scrap on both sides in the x-axis direction because the flexible printed circuit 90 further includes the second unit portion 932, the third unit portion 933 and the fourth unit portion 934.

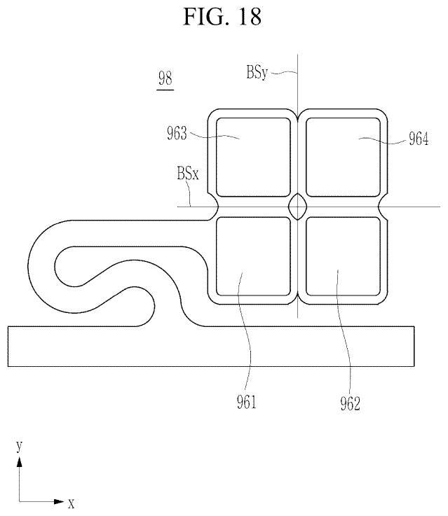

FIG. 18 is a top plan view of the busbar, flexible printed circuit, and unit thin film portion in the rechargeable battery module according to a sixth embodiment of the present disclosure before bending. Referring to FIG. 18, in the sixth embodiment, the unit thin film portions of a flexible printed circuit 98 are formed of four and connected in the first direction (x-axis direction) and in the second direction (y-axis direction).

Unit thin film portions 96 include a first unit portion 961 and a second unit portion 962 continuously extending along the first direction (x-axis direction), and a third unit portion 963 and a fourth unit portion 964 continuously extending along the second direction (y-axis direction) to the first unit portion 961 and the second unit portion 962, and continuously extending along the first direction (x-axis direction).

The third unit portion 963 and the fourth unit portion 964 are bent around one first direction bending axis BSx set in the first direction (x-axis direction), and are each overlapped with the first unit portion 961 and the second unit portion 962. The fourth unit portion 964 and the second unit portion 962 overlapped with each other are bent around the second direction bending axis BSy set in the second direction (y-axis direction), and are overlapped with the first unit portion 961 and the third unit portion 963, which are overlapped with each other.

Compared to a one-layer structure, a two-layer structure, or a three-layer structure, the first plane portion 961, the second plane portion 962, the third plane portion 963, and the fourth unit portion 964 forming a four-layer structure may effectively prevent piercing and pinhole defects during welding.

In the flexible printed circuit 98 of the sixth embodiment, the unit thin film portions 96 generate scrap on both sides of the x-axis direction. The flexible printed circuit 98 of the sixth embodiment, in forming the unit film portions 96, compared to the flexible printed circuit 40 of the first embodiment, generates less scrap on both sides in the x-axis direction because the flexible printed circuit 98 further includes the second unit portion 962, and generates more scrap on both sides in the x-axis direction because the flexible printed circuit 98 further includes the third unit portion 963 and the fourth unit portion 964.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

<Description of symbols>

| | |
|---|---|
| 10: Battery cell | 20: Busbar holder |
| 25: Busbar support | 30: Busbar |
| 40, 50, 60, 80, 90: Flexible printed circuit (FPC) | |
| 41, 42: Cover layer | 43, 53, 63, 83, 93, 96: Unit thin film portion |
| 44, 54: Main line | 45, 55: Branch line |
| 70: Top cover | 411, 421: Opening |
| 431, 531, 631, 831, 931, 961: First unit portion | |
| 432, 532, 632, 832, 932, 962: Second unit portion | |
| 633, 833, 933, 963: Third unit portion | 934, 964: Fourth unit portion |
| BSx, BSx1, BSx2: First direction bending axis | |
| BSy, BSy1, BSy2, BSy3: Second direction bending axis | |
| F1, F21, F31: First plane portion | F2, F22, F32: Second plane portion |
| F33: Third plane portion | S1, S21, S31: First inclined portion |
| S2, S22, S32: Second inclined section | S33: Third inclined portion |
| θ1, θ21, θ31: First inclined angle | θ2, θ22, θ32: Second inclined angle |
| θ33: Third inclined angle | |

What is claimed is:

1. A rechargeable battery module comprising:
a busbar holder covering a plurality of battery cells;
a busbar disposed on the busbar holder to electrically connect the battery cells; and
a flexible printed circuit attached to the busbar, the flexible printed circuit being configured to send a signal and to detect a current in the busbar, the flexible printed circuit including a thin copper film attached between inner surfaces of a pair of cover layers,
wherein the thin copper film is exposed in unit thin film portions through a plurality of openings formed in the pair of cover layers,
wherein the thin copper film and the pair of cover layers are bent, and
wherein the unit thin film portions are formed in multiple layers and welded to the busbar.

2. The rechargeable battery module of claim 1, wherein the unit thin film portion has a thickness of 0.035 mm, and
wherein a thickness of the multiple layers is equal to 0.035 mm multiplied by the number of layers.

3. The rechargeable battery module of claim 1, wherein the flexible printed circuit comprises:
a main line portion disposed in a first direction on the busbar holder; and
a branch line portion protruding from the main line portion in a second direction intersecting the first direction, and disposed further in the first direction, and
wherein the unit thin film portions are connected to the branch line portion.

4. The rechargeable battery module of claim 3, wherein the branch line portion is attached to the busbar.

5. The rechargeable battery module of claim 3, wherein the rechargeable battery module has two unit thin film portions connected in the first direction.

6. The rechargeable battery module of claim 3, wherein the unit thin film portions comprise a first unit portion and a second unit portion continuously extending along the first direction, and
wherein the first unit portion and the second unit portion are bent around a second direction bending axis set in the second direction such that the first unit portion and the second unit portion overlap with each other.

7. The rechargeable battery module of claim 6, wherein the first unit portion comprises a first plane portion connected to a first inclined portion at a first inclined angle θ1,
wherein the second unit portion comprises a second plane portion connected to a second inclined portion at a second inclined angle θ2 that is greater than the first inclined angle θ1, and
wherein the first plane portion and the second plane portion are connected in the second direction, are sequentially stacked on the busbar, and are welded to the busbar.

8. The rechargeable battery module of claim 3, wherein the rechargeable battery module has two of the unit thin film portions connected in the second direction.

9. The rechargeable battery module of claim 3, wherein the unit thin film portions comprise a first unit portion and a second unit portion continuously extending along the second direction, and
wherein the first unit portion and the second unit portion are bent around a first direction bending axis set in the first direction such that the first unit portion and the second unit portion overlap each other.

10. The rechargeable battery module of claim 9, wherein the first unit portion comprises a first plane portion connected to a first inclined portion at a first inclined angle θ21,
wherein the second unit portion comprises a second plane portion connected to a second inclined portion at a second inclined angle θ22 that is greater than the first inclined angle θ21, and
wherein the first plane portion and the second plane portion are connected in the first direction, are sequentially stacked on the busbar, and are welded to the busbar.

11. The rechargeable battery module of claim 3, wherein the rechargeable battery module has three of the unit thin film portions connected in the second direction.

12. The rechargeable battery module of claim 3, wherein the unit thin film portions comprise a first unit portion, a second unit portion, and a third unit portion continuously extending along the second direction,
wherein the first unit portion and the second unit portion are bent around a first direction bending axis set in the first direction such that the first unit portion and the second unit portion overlap with each other, and
wherein the second unit portion and the third unit portion are bent around another first direction bending axis set in the first direction such that the second unit portion and the third unit portion overlap with each other.

13. The rechargeable battery module of claim 12, wherein the first unit portion comprises a first plane portion connected to a first inclined portion at a first inclined angle θ31,
wherein the second unit portion comprises a second plane portion connected to a second inclined portion at a second inclined angle θ32 that is greater than the first inclined angle θ31,
wherein the third unit portion comprises a third plane portion connected to a third inclined portion at a third inclined angle θ33 that is greater than the second inclined angle θ32, and
wherein the first plane portion, the second plane portion, and the third plane portion are connected in the second direction, are sequentially stacked on the busbar, and are welded to the busbar.

14. The rechargeable battery module of claim 3, wherein the rechargeable battery module has three of the unit thin film portions connected in the first direction.

15. The rechargeable battery module of claim 3, wherein the unit thin film portions comprise a first unit portion, a second unit portion, and a third unit portion continuously extending along the first direction,
wherein the first unit portion and the second unit portion are bent around a second direction bending axis set in the second direction such that the first unit portion and the second unit portion overlap with each other, and
wherein the second unit portion and the third unit portion are bent around another second direction bending axis set in the second direction such that the second unit portion and the third unit portion overlap with each other.

16. The rechargeable battery module of claim 3, wherein the unit thin film portions comprise a first unit portion, a second unit portion, a third unit portion, and a fourth unit portion continuously extending along the first direction,
wherein the first unit portion and the second unit portion are bent around a second direction bending axis set in the second direction such that the first unit portion and the second unit portion overlap with each other,
wherein the second unit portion and the third unit portion are bent around another second direction bending axis set in the second direction such that the second unit portion and the third unit portion overlap with each other, and
wherein the third unit portion and the fourth unit portion are bent around the other second direction bending axis set in the second direction such that the third unit portion and the fourth unit portion overlap with each other.

17. The rechargeable battery module of claim 3, wherein the rechargeable battery module has four of the unit thin film portions connected in the first direction and the second direction.

18. The rechargeable battery module of claim 3, wherein the unit thin film portions comprise a first unit portion and a second unit portion continuously extending along the first direction; and
wherein the unit film portions comprise a third unit portion and a fourth unit portion continuously extending along the second direction, connected to the first unit portion and the second unit portion, and continuously extending along the first direction.
